(19) United States
(12) Patent Application Publication
(10) Pub. No.: US 2010/0151688 A1
(43) Pub. Date: Jun. 17, 2010

(54) METHOD TO PREVENT THIN SPOT IN LARGE SIZE SYSTEM

(75) Inventors: Young Jin Choi, Santa Clara, CA (US); Gaku Furuta, Sunnyvale, CA (US); Soo Young Choi, Fremont, CA (US); Beom Soo Park, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, INC., Santa Clara, CA (US)

(21) Appl. No.: 12/634,921

(22) Filed: Dec. 10, 2009

Related U.S. Application Data
(60) Provisional application No. 61/122,290, filed on Dec. 12, 2008.

(51) Int. Cl. H01L 21/3065; H01L 21/302

(52) U.S. Cl. 438/716; 438/758; 257/E21.218; 257/E21.214

(57) ABSTRACT

Embodiments disclosed herein generally include methods of ensuring uniform deposition on a substrate. The smallest gap between a portion of the substrate and the substrate support upon which the substrate rests may lead to uneven deposition of material or ‘thin spots’ on the substrate. Large area substrates, due to their size, are susceptible to numerous gaps at random locations. By inducing an electrostatic charge on the substrate prior to placing the substrate onto the substrate support, the substrate may be placed generally flush against the substrate support. The electrostatic charge on the substrate creates an attraction between the substrate and substrate support to pull substantially the entire surface of the substrate into contact with the substrate support. Material may then be substantially uniformly deposited on the substrate while reducing ‘thin spots’.

### CROSS-REFERENCE TO RELATED APPLICATIONS

This application claims benefit of U.S. Provisional Patent Application Ser. No. 61/122,290 (APPM/14129L), filed Dec. 12, 2008, which is herein incorporated by reference.

### BACKGROUND OF THE INVENTION

1. Field of the Invention

Embodiments disclosed herein generally relate to a method for ensuring uniform deposition on a substrate.

2. Description of the Related Art

As the demand for larger flat panel displays (FPDs) continues to grow, so does the size of the substrate that is used to make the FPDs. The size of the substrates now routinely exceeds 1 square meter in area. When compared to the size of semiconductor substrates, which typically are about 300 centimeters in diameter, it can be easily understood that a chamber sized to process a semiconductor wafer may not be sufficiently large to process a substrate of 1 square meter or larger. Thus, larger area processing chambers need to be developed.

These large area processing chambers may, in some cases, be identical to the semiconductor counterpart chambers where simply scaling up in size achieves acceptable results. In other cases, scaling up the size of the processing chamber is not effective as unforeseen difficulties occur when scaling up the processing chambers. Therefore, care needs to be taken to design a chamber that can process large area substrates.

Additionally, the process conditions for processes that are performed in the large area processing chambers may need to be adjusted. Determining proper gas flows, timing sequences, power to apply, temperature conditions, and other process variables may require a significant amount of research and experimentation that is beyond routine.

Therefore, there is a need for new and non-obvious methods for processing large area substrates.

### SUMMARY OF THE INVENTION

Embodiments disclosed herein generally include methods of ensuring uniform deposition on a substrate. The smallest gap between a portion of the substrate and the substrate support upon which the substrate rests may lead to uneven deposition of material or ‘thin spots’ on the substrate. Large area substrates, due to their size, are susceptible to numerous gaps at random locations. By inducing an electrostatic charge on the substrate prior to placing the substrate onto the substrate support, the substrate may be placed generally flush against the substrate support. The electrostatic charge on the substrate creates an attraction between the substrate and substrate support to pull substantially the entire surface of the substrate into contact with the substrate support. Material may then be substantially uniformly deposited on the substrate while reducing ‘thin spots’.

In one embodiment, a method includes inserting a substrate into a chamber on an end effector and lowering the end effector to place the substrate onto one or more lift pins. The method may also include retracting the end effector from the chamber, introducing a gas into the chamber, igniting the gas into a plasma, and extinguishing the plasma. The method may also include exhausting the gas from the chamber and raising a substrate support from a first position to a second position such that the substrate rests on the substrate support.

In another embodiment, a method includes introducing a gas into a chamber, igniting the gas into a plasma while a substrate is spaced from a substrate support, and bringing the substrate into contact with the substrate support.

In another embodiment, a method includes inducing an electrostatic charge onto a substrate while the substrate is spaced from a substrate support and bringing the substrate into contact with the substrate support.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of a processing chamber according to one embodiment.

FIG. 2A is a schematic top view of a substrate having a layer deposited thereon that has thin spots.

FIG. 2B is a schematic cross sectional view of FIG. 2A taken along line A-A.

FIG. 3 is a schematic cross sectional view of a large area substrate disposed on a substrate support.

FIGS. 4A-4D are schematic cross sectional views showing a sequence of placing a substrate into a chamber according to one embodiment.

FIGS. 5A-5C are graphs showing a comparison of film thickness variations according to several embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments discussed herein relate to methods of ensuring a substantially uniformly thick layer is deposited onto a substrate. In the description that follows, reference will be made to a plasma enhanced chemical vapor deposition (PECVD) chamber, but it is to be understood that the embodiments herein may be practiced in other chambers as well, including physical vapor deposition (PVD) chambers, etching chambers, semiconductor processing chambers, solar cell processing chambers, and organic light emitting display (OLED) processing chambers to name only a few. Suitable chambers that may be used are available from AKT America, Inc., a subsidiary of Applied Materials, Inc., Santa Clara, Calif. It is to be understood that the embodiments discussed herein may be practiced in chambers available from other manufacturers as well.

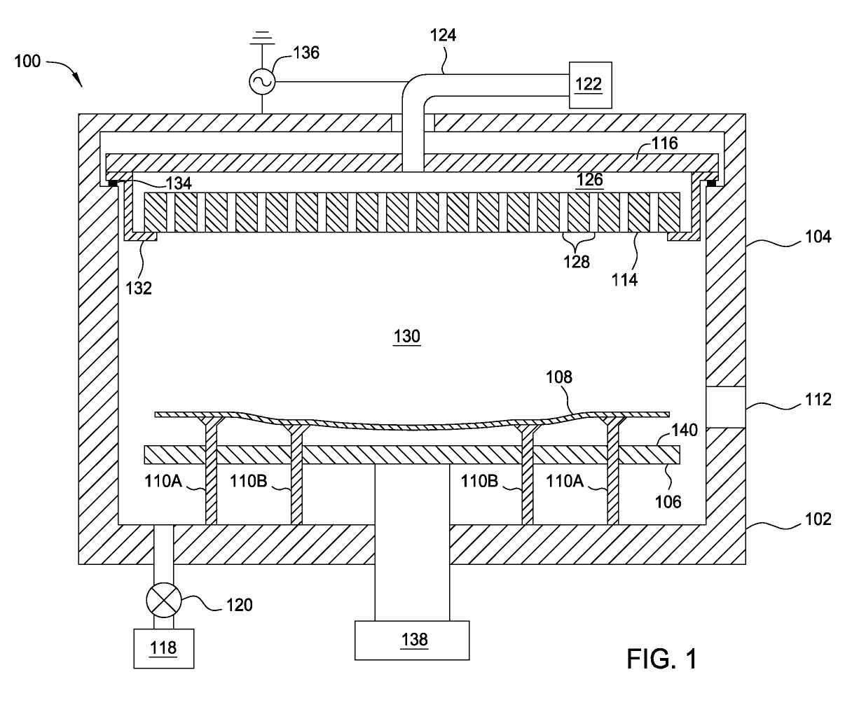

FIG. 1 is a schematic cross sectional view of a processing chamber 100 according to one embodiment. The chamber 100 includes a chamber body 102 having a lid 104 coupled thereto. In one embodiment, the chamber body 102 and the lid 104 may comprise aluminum. Within the chamber body 102, a substrate support 106 may be present to support a substrate 108 during processing. In one embodiment, the substrate 108 may comprise glass. One or more lift pins 110A, 110B may extend through the substrate support 106 to support the substrate 108 when the substrate 108 is received from an end effector and when the substrate is ready to be received by an end effector. In one embodiment, the lift pins 110A, 110B may comprise a ceramic material. The lift pins 110A, 110B may rest on the bottom of the chamber body 102 and support the substrate 108 when the substrate support 106 is lowered by an actuator 138. In one embodiment, the substrate support 106 may comprise a conductive material. In another embodiment, the substrate support 106 may comprise aluminum. In another embodiment, the substrate support 106 may have a coating of anodized aluminum thereover.

A showerhead 114 may be present within the chamber 100 and disposed opposite the substrate support 106. The showerhead 106 may be electrically coupled to a backing plate 116 by a bracket 132. In one embodiment, the showerhead 114, backing plate 116, and bracket 132 may each comprise a conductive material. In another embodiment, the showerhead 114, backing plate 116, and bracket 132 may comprise aluminum.

Gas may be delivered to the chamber 100 from a gas source 122 through a tube 124 that passes through the lid 124 and couples to the backing plate 116. The gas then travels through the backing plate 116 and disperses within a plenum 126 between the backing plate 116 and the showerhead 114. The gas substantially evenly distributes within the plenum 126 and then travels through gas passages 128 formed through the showerhead 114. The gas, when depositing material, is ignited into a plasma within the processing area 130 between the substrate 108 and the showerhead 114. The chamber 100 may be evacuated by a vacuum pump 118 that is coupled to the chamber body 102. A valve 120 may be present to regulate the vacuum level.

The plasma may be ignited in the chamber 100 by supplying power from a power source 136. In one embodiment, the power source 136 may comprise an RF power source. In one embodiment, the power source 136 may generate RF currents having a frequency of between about 10 MHz and about 60 MHz. The power source 136 is coupled to the tube 124 that feeds the gas into the chamber 100. The RF current travels along the outside surface of the tube 124 and does not penetrate into the inside of the tube 124 due to the skin effect of RF current. The gas traveling within the tube 124 therefore does not ignite into a plasma within the tube 124.

The RF current travels along the back surface of the backing plate 116, down along the bracket 132 and along the front surface of the showerhead 114 facing the substrate 108. The RF current returns along the walls of the chamber body 102 as well as the lid 104 until it returns to the power source 136.

To perform a process in the chamber 100, a substrate 108 is first inserted into the chamber 100 through the slit valve opening 112 on an end effector. At this time, the substrate support 106 is in a lowered position such that the lift pins 110A, 110B extend above the substrate receiving surface 140 of the substrate support 106. The end effector then lowers, as does the substrate 108 supported thereon, such that the substrate rests on the lift pins 110A, 110B.

The lift pins 110A, 110B have different heights. The lift pins 110A that are disposed near the edge of the substrate support 106 extend to a greater height than the lift pins 110B that are closer to the center. Thus, the substrate 108, when placed onto the lift pins 110A, 110B, sags down as shown in FIG. 1. The substrate 108 sags due to its size. The inner lift pins 110B, extending to a shorter height than the outer lift pins 110B, permit the center of the substrate 108 to sag closer to the substrate support 106 than the outer lift pins 110A. Thus, the substrate 108, when resting on the lift pins 110A, 110B and spaced from the substrate support 106, has a convex surface facing the substrate support 106.

After depositing the substrate 108 onto the lift pins 110A, 110B, the end effector retracts from the chamber 100. The substrate support 106 then raises while the lift pins 110A, 110B remain stationary. The substrate support 106 rises until it is in the processing position. While on the way to the processing position, the substrate support 106 comes into contact with the substrate 108 supported by the lift pins 110A, 110B. The substrate 108 begins to contact the substrate support 106 in a center to edge manner due to the sagging of the substrate 108. The lift pins 110A, 110B remain stationary as the substrate support 106 raises until the substrate support 106 has raised to a position such that the substrate 108 supported by the lift pins 110A, 110B is supported by the substrate support 106. Thus substrate support 106 then continues to raise and thus lifts not only the substrate 108, but also the lift pins 110A, 110B. Because the lift pins 110A, 110B have different lengths, the inner lift pins 110B are raised by the substrate support 106 prior to the outer lift pins 110A. Nonetheless, both sets of lift pins 110A, 110B are raised by the substrate support 106 along with the substrate 108.

Once the substrate support 106 is in the processing position and supports the substrate 108 and lift pins 110A, 110B, the substrate 108 may be processed. In a PECVD process, a processing gas is introduced through the showerhead 114 and ignited into a plasma that causes material to be deposited onto the substrate 108. The plasma may cause an electrostatic charge to build up on the substrate 108. During processing, the substrate support 106 may function as part of the RF return path, or as others refer, ground relative to the hot (or RF biased) showerhead 114.

Following processing, the substrate support 106 is lowered. As the substrate support is lowered 106, the lift pins 110A, 110B will eventually come into contact with the bottom of the chamber body 102. The outer lift pins 110A, due to their length, will contact the bottom of the chamber body 102 before the inner lift pins 110B. Thus, the substrate 108 will begin to separate from the substrate support 106 in an edge to center progression until the substrate 108 is entirely supported by the lift pins 110A, 110B and spaced from the substrate support 106. An end effector may then enter into the chamber below the substrate 108, raise up to lift the substrate 108 off of the lift pins 110A, 110B, and retract the substrate 108 from the chamber 100.

However, problems may occur in separating the substrate 108 from the substrate support 106. The substrate 108 may be more tightly adhered to the substrate support 106 due to the electrostatic charge that has built up on the substrate 108 and/or the substrate support 106. The electrostatic force may cause the substrate 108 to adhere to the substrate support 106 sufficiently such that overcoming the electrostatic force may damage the substrate 108.

Therefore, to overcome the electrostatic charge that has built up on the substrate 108 and substrate support 106, the substrate 108 may be power lifted from the substrate support 106. To power lift the substrate 108 from the substrate support 106, a gas may be introduced into the chamber 100. The gas may be a gas that does not chemically react with the processed substrate 108. If a gas that chemically reacts with the substrate 108 were used, then undesirable processing of the substrate 108 may occur. Therefore, the gas should be chemically inert relative to the processed substrate 108. In one embodiment, the gas may be selected from hydrogen, nitrogen, argon, and ammonia.

The gas that has been introduced is ignited into a plasma. In one embodiment, the RF power used to ignite the plasma is lower than the RF power applied to generate the plasma used to deposited material onto the substrate 108. The processed substrate 108 is exposed to the plasma for a predetermined time period. In one embodiment, the time period is between about 5 seconds and about 15 seconds. Not wishing to be bound by theory, it is believed that the plasma of non-reactive gas removes, reduces or redistributes the electrostatic charge built up on the substrate 108 and substrate support 106 such that the substrate 108 may be removed from contact with the substrate support 106 without damaging the substrate 108. The removal, reduction or redistribution of the electrostatic charge reduces the stiction between the substrate 108 and the substrate support 106 and thus allows the substrate 108 to be more easily separated from the substrate support 106. By using a power lower than used for the depositing of material, the charge applied to the substrate 108 and the substrate support 106 during the power lifting is limited.

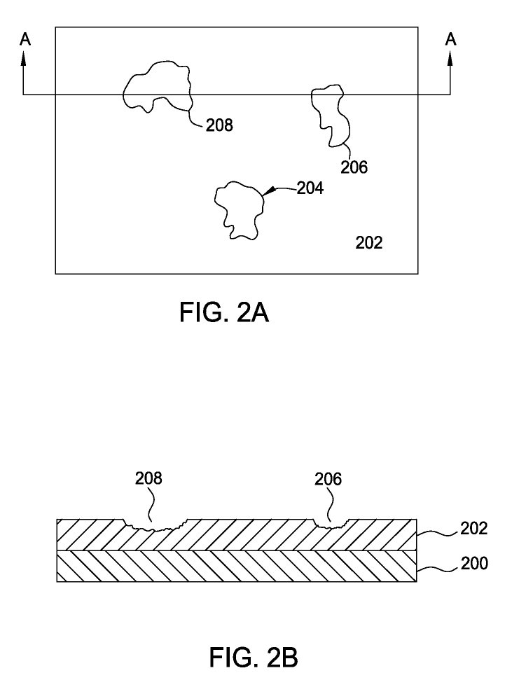

Unfortunately, material does not always deposit uniformly onto a substrate. FIG. 2A is a schematic top view of a substrate having a layer 202 deposited thereon that has thin spots 204, 206, 208. FIG. 2B is a schematic cross sectional view of FIG. 2A taken along line A-A. As shown in FIGS. 2A and 2B, the layer 202 is deposited over the substrate 200, but the film does not have a uniform thickness across the layer. The thin spots 204, 206, 208, are locations where the deposited material is not as thick. Due to the thin spots 204, 206, 208, the layer 202 is not uniform across the substrate 200. The thin spots may be randomly distributed across the layer 202.

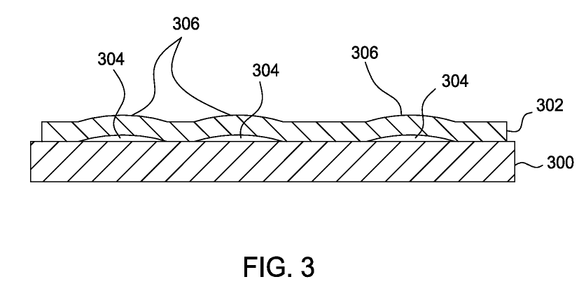

Thin spots may be caused by the substrate not being perfectly flush with the substrate support during processing. FIG. 3 is a schematic cross sectional view of a large area substrate 302 disposed on a substrate support 300. As can be seen from FIG. 3, one or more gaps 304 may be present between the substrate support 300 and the substrate 302. Because of the gaps 304, portions of the substrate 302 are higher than others such that bumps 306 are present. Even though the substrate 302 may contact the substrate support 300 in a center to edge progression as discussed above, air may still get trapped between the substrate 302 and the substrate support 300. Not wishing to be bound by theory, it is believed that the gaps 304, which cause bumps 306 in the substrate 302, may lead to the thin spots in material deposited over the substrate 302.

Not wishing to be bound by theory, it is believed that the thin spots may form on the substrate 302 having the bumps 306 because the deposited material may tend to deposit in the lower areas and build up. The material would continue to deposit until the desired thickness has been reached. Once the desired thickness has been reached, the top surface of the film is expected to be substantially planar. However, if the gaps 304 between the substrate support 300 and the substrate 302 are removed, the bumps 306 are gone. The material deposited on the substrate 302 would no longer be planar due to the absence of the bumps 306. While no material has disappeared, the layer, because the bumps 306 are gone, is no longer planar. Where the bumps 306 once were, thin spots are present in the deposited layer.

Another reason that the thin spots may form is due to the plasma density. In the chamber shown in FIG. 1, the showerhead 114 is ‘hot’ because it is connected to the RF power source 136. The substrate support 106 is part of the RF return path and is considered to be ‘RF grounded’. The gaps 304 between the substrate 302 and the substrate support 300 may lead to an uneven power density distribution within the chamber at the gaps 304. If the substrate 302 is flush against the substrate support 302, it is believed that the plasma density will be substantially symmetrical.

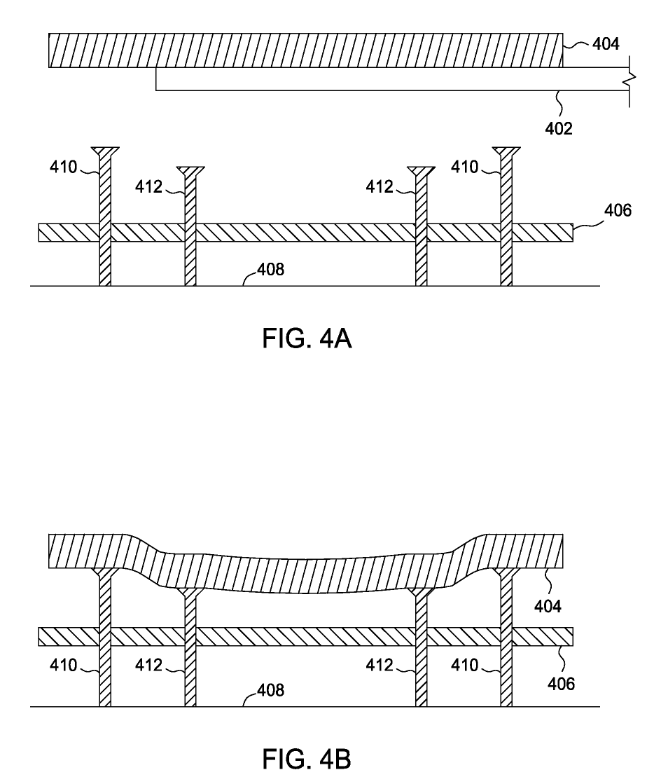

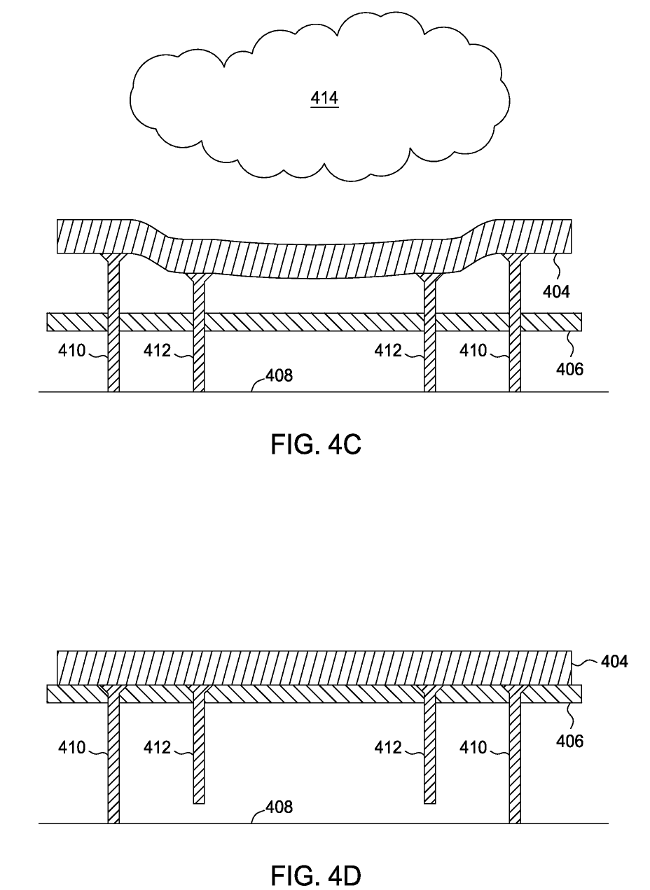

To ensure symmetrical plasma density, it would be beneficial to have the substrate flush against the substrate support. FIGS. 4A-4D are schematic cross sectional views showing a sequence of placing a substrate into a chamber according to one embodiment such that the substrate is flush against the substrate support. The sequence may be referred to as a pre-plasma loading sequence.

As shown in the figures, a substrate 404 is supported by an end effector 402 as it is brought into a processing chamber. The end effector 402 is then lowered to place the substrate 404 on the lift pins 410, 412 that extend from the bottom 408 of the chamber through the substrate support 406. Once the substrate 404 is resting on the lift pins 410, 412, the end effector is retracted from the chamber.

While the substrate 404 is resting on the lift pins 410, 412 and before the substrate 404 rests on the substrate support 406, a gas may be introduced into the chamber. The gas may comprise a gas that does not chemically react with the substrate 404 or cause any deposition onto the substrate 404. Examples of gases that may be used include hydrogen, nitrogen, ammonia, argon, and combinations thereof. The gas is then ignited into a plasma.

Similar to the situation that occurs during plasma deposition discussed above, an electrostatic charge develops on the substrate 404 and/or the substrate support 406. The power applied to ignite the plasma may be discontinued and the chamber may then be pumped down to the base pressure for processing. The substrate support 406 may then be raised and the substrate 404 may contact the substrate support 406 in a center to edge manner at a slow speed. The substrate support 406 is raised without any gas or plasma until the substrate 404 is supported by the substrate support 406. It is only after the plasma is extinguished that the substrate support 406 is raised.

The electrostatic charge that has built up on the substrate 404 and/or the substrate support 406 may pull the substrate 404 into greater contact with the substrate support 406 such that the amount of gaps that may be present between the substrate 404 and the substrate support 406 may be reduced below what would be present in absence of the pre-plasma loading process.

Once the substrate 404 is supported by the substrate support 406, processing gases may be introduced into the chamber and ignited into a plasma by RF power. The substrate 404 may thus be processed. The substrate 404 may then be power lifted off of the substrate support 406 as discussed above.

In addition to building up electrostatic charge on the substrate 404 and/or substrate support 406, it is believed that the ignited plasma heats the substrate 404 and enables the substrate 404 to be more flexible. The greater the flexibility of the substrate 404, the less likely gaps may form between the substrate 404 and the substrate support 406 during the center to edge progression.

The pre-plasma loading discussed above is distinct from what has been termed ‘plasma loading’. Plasma loading is a process for thermophoresis that is used to heat the substrate to a temperature greater than its surroundings. Because the substrate is heated to a temperature greater than its surroundings, any negatively charged particles or other contaminants tend to gravitate towards the coolest surface. When a substrate is introduced into a processing chamber, the substrate may be the coolest surface and thus, risk contamination. By heating the substrate to a temperature greater than the surroundings, the negatively charged particles may gravitate to a surface other than the substrate. Plasma loading, which is different from the pre-plasma loading discussed above, involves rapidly raising the temperature of the substrate.

A plasma loading sequence involves inserting a substrate into a processing chamber and placing the substrate onto the substrate support. No plasma is ignited prior to placing the substrate onto the substrate support. Then, the pressure of the chamber is increased above the normal processing pressure. An inert gas such as a noble gas or a gas that does not chemically react with the substrate is introduced into the chamber and ignited into a plasma. The plasma heats the substrate up to a temperature that is greater than the other electrode (a showerhead in a PECVD system). Then, the plasma is extinguished, the gas evacuated, and the pressure reduced to normal. The substrate may then be processed. Alternatively, plasma loading may comprise igniting a plasma while the substrate support is moving upwards to make contact with the substrate, which is still different than pre-plasma loading where the plasma is ignited and extinguished before the substrate support ever moves.

Because the substrate is brought into contact with the substrate support prior to igniting the plasma in a plasma loading, plasma loading and pre-plasma loading are different. Additionally, pre-plasma loading may occur at the normal operating pressures rather than an increased pressure. By inducing an electrostatic charge on the substrate and/or substrate support prior to the substrate resting on the substrate support, the gaps or bumps may be reduced and/or avoided. On the other hand, plasma loading does not induce an electrostatic charge until after the substrate is resting on the substrate support.

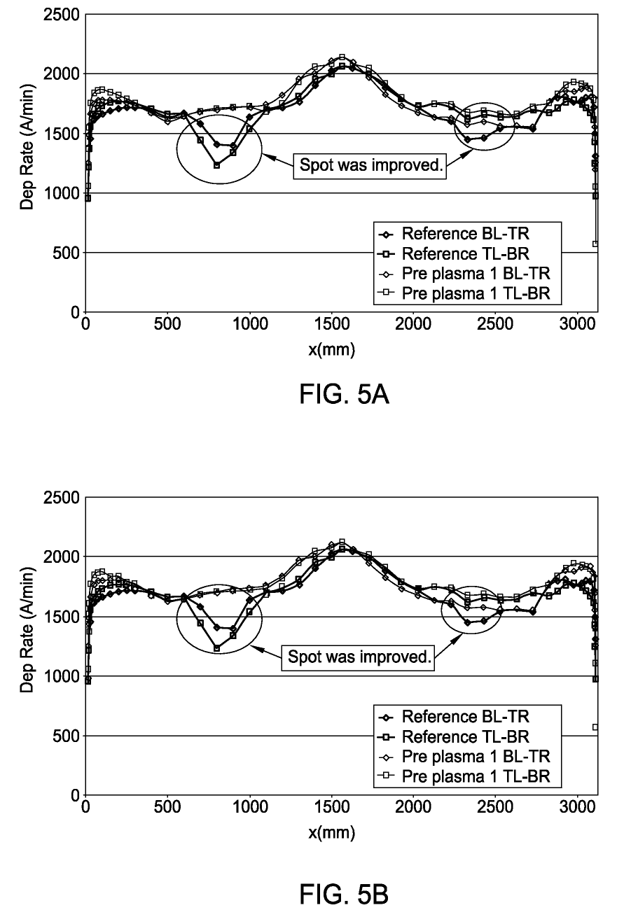

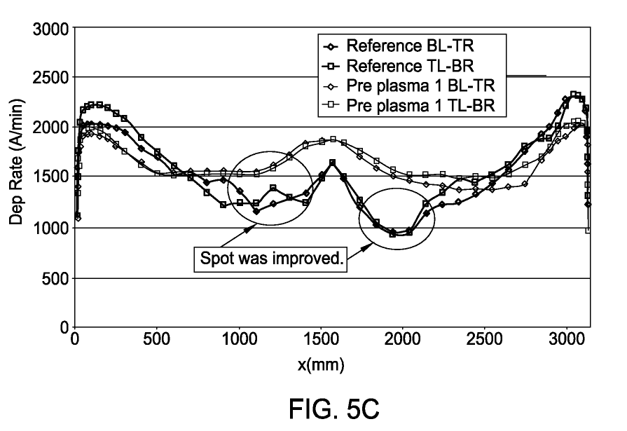

FIGS. 5A-5C are graphs showing a comparison of film thickness variations according to several embodiments. In each of FIGS. 5A-5C, it can be seen that when pre-plasma loading occurs, the deposited film has greater uniformity. When no-pre-plasma processing occurs, thin spots are present. The lines labeled “reference BL-TR” and “reference TL-BR” are results for depositions onto substrates that were not pre-plasma loaded. The lines labeled “Pre-plasma” are results for depositions onto substrates that were pre-plasma loaded.

In the embodiments discussed above, large area substrates may be subject to a pre-plasma process whereby an electrostatic charge may be induced onto a substrate and/or a substrate support prior to coming into contact with each other. By inducing an electrostatic charge, the substrate and substrate support may be brought into intimate contact with each other such that few gaps, if any, are present between the substrate and substrate support. Because few gaps, if any, are present, the plasma density during plasma processing may be substantially symmetrical such that a uniformly thick film is deposited over the substrate.

While the embodiments discussed above have referred to large area substrates, it is believed that the pre-plasma loading may be beneficial to smaller substrates as well. The benefits of using the pre-plasma loading for smaller substrates include the symmetrical plasma density as discussed above, and also potentially the removal of a clamp ring to press the substrate into intimate contact with the substrate support.

While the foregoing is directed to embodiments of the present invention, other and further embodiments of the invention may be devised without departing from the basic scope thereof, and the scope thereof is determined by the claims that follow.

1. A method, sequentially comprising:
inserting a substrate into a chamber on an end effector;
lowering the end effector to place the substrate onto one or more lift pins;
retracting the end effector from the chamber;
introducing a gas into the chamber;
igniting the gas into a plasma;
extinguishing the plasma;
exhausting the gas from the chamber; and
raising a substrate support from a first position to a second position such that the substrate rests on the substrate support.

2. The method of claim 1, wherein the gas is an inert gas.

3. The method of claim 1, wherein the gas is a nitrogen containing gas.

4. The method of claim 1, wherein the gas does not comprise silicon.

5. The method of claim 1, further comprising performing a process on the substrate, the process selected from the group consisting of depositing and etching.

6. The method of claim 5, wherein the process is a plasma enhanced chemical vapor deposition process.

7. The method of claim 1, further comprising:
exposing the substrate to a processing gas after the substrate rests on the substrate support, the processing gas comprising a material that chemically reacts to either deposit a material on the substrate or remove material from the substrate;
processing the substrate with the processing gas;
exposing the substrate to a gas that does not chemically react with the processed substrate;
igniting the gas that does not chemically react with the processed substrate into a plasma; and
spacing the substrate from the substrate support.

8. The method of claim 7, wherein the exposing the substrate to a gas that does not chemically react with the processed substrate occurs after the substrate support has been raised to the second position such that the substrate rests on the substrate support.

9. A method, comprising:
introducing a gas into a chamber;
igniting the gas into a plasma while a substrate is spaced from a substrate support; and then
bringing the substrate into contact with the substrate support.

10. The method of claim 9, wherein the gas is an inert gas.

11. The method of claim 9, wherein the gas is a nitrogen containing gas.

12. The method of claim 9, wherein the gas does not comprise silicon.

13. The method of claim 9, further comprising performing a process on the substrate after bringing the substrate into contact with the substrate support, the process selected from the group consisting of depositing and etching.

14. The method of claim 13, wherein the process is a plasma enhanced chemical vapor deposition process.

15. The method of claim 9, further comprising:
exposing the substrate to a processing gas after the substrate is in contact with the substrate support, the processing gas comprising a material that chemically reacts to either deposit a material on the substrate or remove material from the substrate;
processing the substrate with the processing gas;
exposing the substrate to a gas that does not chemically react with the processed substrate;
igniting the gas that does not chemically react with the processed substrate into a plasma; and
spacing the substrate from the substrate support.

16. The method of claim 15, wherein the exposing the substrate to a gas that does not chemically react with the processed substrate occurs after the substrate support has been raised to the second position such that the substrate rests on the substrate support.

17. A method, comprising:
inducing an electrostatic charge onto a substrate while the substrate is spaced from a substrate support; and
bringing the substrate into contact with the substrate support.

18. The method of claim 17, further comprising processing the substrate after the substrate is in contact with the substrate support.

19. The method of claim 18, further comprising:
exposing the substrate to a gas that does not chemically react with the substrate;
igniting the gas into a plasma; and
spacing the substrate from the substrate support.

20. The method of claim 17, further comprising heating the substrate prior to bringing the substrate into contact with the substrate support.
